(19) United States
(12) Patent Application Publication
(10) Pub. No.: US 2008/0225490 A1
(43) Pub. Date: Sep. 18, 2008

(54) Thermal interface materials

(76) Inventor: Daewoong Suh, Phoenix, AZ (US)

Correspondence Address: CAVEN & AGHEVLI;c/o INTELLEVATE, LLC, P.O. BOX 52050, MINNEAPOLIS, MN, 55402, US

(21) Appl. No.: 11/724,678

(22) Filed: Mar. 15, 2007

(51) Int. Cl. H05K 7/20

(52) U.S. Cl. 361/705; 361/718

(57) ABSTRACT

In one embodiment, an apparatus comprises a semiconductor device a heat dissipation assembly, and a thermal interface material disposed between the semiconductor device and the heat dissipation assembly, wherein the thermal interface layer comprises an alloy having a low indium content.

### BACKGROUND

The subject matter described herein relates generally to the field of electronic devices and more particularly to thermal interface materials.

Electronic components, including integrated circuits, may be assembled into component packages by physically and electrically coupling them to a substrate. During operation, the component package may generate heat that can be dissipated to help maintain the circuitry at a desired temperature. Heat sinks, heat spreaders, and other heat dissipating elements may be attached to the package via a suitable thermal interface material.

Thermal interface materials have been made from Indium. Additional materials to make thermal interface materials may find utility.

### BRIEF DESCRIPTION OF THE DRAWINGS

The detailed description is described with reference to the accompanying figures.

FIG. 1 is a cross-sectional, schematic illustration of an electronic device adapted to accommodate a thermal interface in accordance with some embodiments.

FIG. 2 is a schematic illustration of a phase diagram for a thermal interface material in accordance with some embodiments.

FIGS. 3 is a graph illustrating compositions of thermal interface alloys, according to embodiments.

FIG. 4 is a schematic illustration of a phase diagram for a thermal interface material in accordance with some embodiments.

FIG. 5 is a schematic illustration of a computing system which may incorporate a thermal interface in accordance with some embodiments.

### DETAILED DESCRIPTION

Described herein are exemplary thermal interfaces which may be used in electronic system such as, e.g., computing systems. In the following description, numerous specific details are set forth to provide a thorough understanding of various embodiments. However, it will be understood by those skilled in the art that the various embodiments may be practiced without the specific details. In other instances, well-known methods, procedures, components, and circuits have not been illustrated or described in detail so as not to obscure the particular embodiments.

In some embodiments the thermal interfaces described herein may be implemented to transfer heat from surfaces of electronic components such as, e.g., integrated circuits (ICs). In alternate embodiments the thermal interfaces described herein may be implemented to transfer heat in any setting where heat is to be conducted from one surface to another. For ease of explanation, the example of cooling an IC will be described.

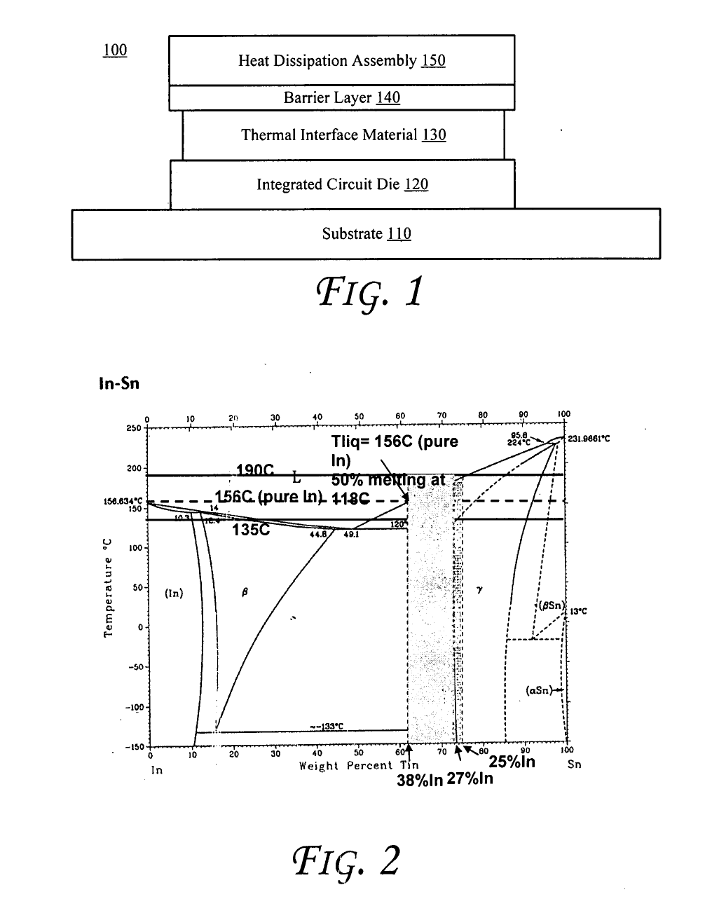

FIG. 1 is a cross-sectional, schematic illustration of an electronic device adapted to accommodate a thermal interface in accordance with some embodiments. Referring to FIG. 1, electronic device 100 includes an IC die 120 coupled to an upper surface of a substrate 110, such as a circuit board. Substrate 110 can be a one-layer circuit board or a multi-layer circuit board.

IC die 120 generates its heat from internal structure, including wiring traces. Heat generated by IC die 120 may be dissipated by a heat dissipation assembly 150. In some embodiments, heat dissipation assembly 150 may include a heat spreader to dissipate heat into the ambient environment. The heat spreader may be active, i.e., it may utilize one or more fans to dissipate heat, or passive, i.e., it may rely on convection to dissipate heat. In some embodiments, heat dissipation assembly 150 may include a heat pipe assembly that utilizes a fluid such as, e.g., water or oil, to dissipate heat generated by the integrated circuit die 120.

A thermal interface material 130 is disposed between the integrated circuit die 120 and the heat dissipation assembly 150 to establish a thermal pathway between the integrated circuit die 120 and the heat dissipation assembly 150. In some embodiments, thermal interface material 130 comprises at least one of an indium alloy, an indium-tin alloy, an indium-silver alloy, a boron-nitride compound, or a lead-tin alloy. Thermal interface material may include a polymer base such as, e.g., a grease, a gel, or a precious-metal clay (PMC).

A barrier layer 140 is disposed between the thermal interface material 130 and the heat dissipation assembly 150. Barrier layer 140 may be formed from a material such as, e.g., nickel, which inhibits intermetallic interaction between the heat dissipation assembly 150 and the thermal interface material 130. In some embodiments, barrier layer 140 may be formed as a separate structural element, which may be positioned between thermal interface material 130 and heat dissipation assembly 150. In some embodiments, barrier layer 140 may be coated onto a surface of either (or both) of thermal interface material 130 or heat dissipation assembly 150, e.g., by nickel plating, dipping, brushing, coating, or depositing a layer of nickel onto the surface. Barrier layer 140 may, in some embodiments, also promote adhesion with the TIM

Alloy thermal interface materials (TIMs) are expected to provide performance comparable to pure indium TIMs if they meet the following boundary conditions. First, the melting point (TM) should exceed 110 degrees centigrade (110 C), so that the TIM can form reliable joints during operation and can accommodate temperature cycling. Second, the bulk thermal conductivity (K) of the alloy should exceed 28 W/Km with 3 mil BLT for equivalent Rjc (for comparable EOL thermal performance).

$$\begin{matrix}\begin{matrix}{( \frac{BLT}{K} )}_{alloy} = {( \frac{BLT}{K} )}_{POR} \\ or \\ {( \frac{PTH}{K} )}_{alloy} = {( \frac{PTH}{K} )}_{POR}\end{matrix} \\ \begin{matrix}{K}_{alloy} [ \text{W/Km} ] = \frac{{PTH}_{alloy}}{{( PTH / K )}_{POR}} \\ = ( \text{3mil/9mil} ) 84 \text{W/Km} = 28\end{matrix} \\ Assumption \\ BLT = kPTH ; k ( \leq 1 ) is constant for \\ all TIM . Typically , k \sim 0.8 for \\ indium preform\end{matrix} \qquad$$

FIG. 2 is a schematic illustration of a phase diagram for a thermal interface material in accordance with some embodiments. The thermal interface material depicted in FIG. 2 comprises an alloy of tin (Sn) and Indium (In). Referring to FIG. 2, pure Indium has a melting temperature of 156 C, and exhibits 50% melting at 118 C. As illustrated in FIG. 2, an alloy of tin (Sn) and Indium (In) can produce the following characteristics:
Sn-(25-27%) In: Tliquidus=190-185 C and Tsolidus=140-135 C
Sn-(27-38%) In: Tliquidus=185-156 C and Tsolidus=118 C
The thermal conductivity of this alloy is between 34 to 50 W/Km.

In another embodiment, the alloy may include a ternary peritectic such as, for example, an alloy of Sn—In—Ag. For example, an alloy of Sn-25%In-2.5% Ag provides Tliquidus=183 C and Tsolidus=180 C.

In another embodiment, the alloy may include a ternary eutectic such as, for example, an alloy of Sn—Zn—Mg. For example, an alloy of Sn-9% Zn-6% Mg provides a melting temperature (TM) of 182 C and thermal conductivity of approximately 60 W/Km.

In another embodiment, the alloy may include aernary eutectic such as, for example, an alloy of Sn—Zn—Mg. For example, an alloy of Sn—Zn—Mg+X, where X represents one of Ag/Au/Bi/CuIn/YIYb may be used. In embodiments, an alloy may be composed of Sn-9% Zn-6% Mg+X% of Ag/Au/Bi/Cu/In/Y/Yb.

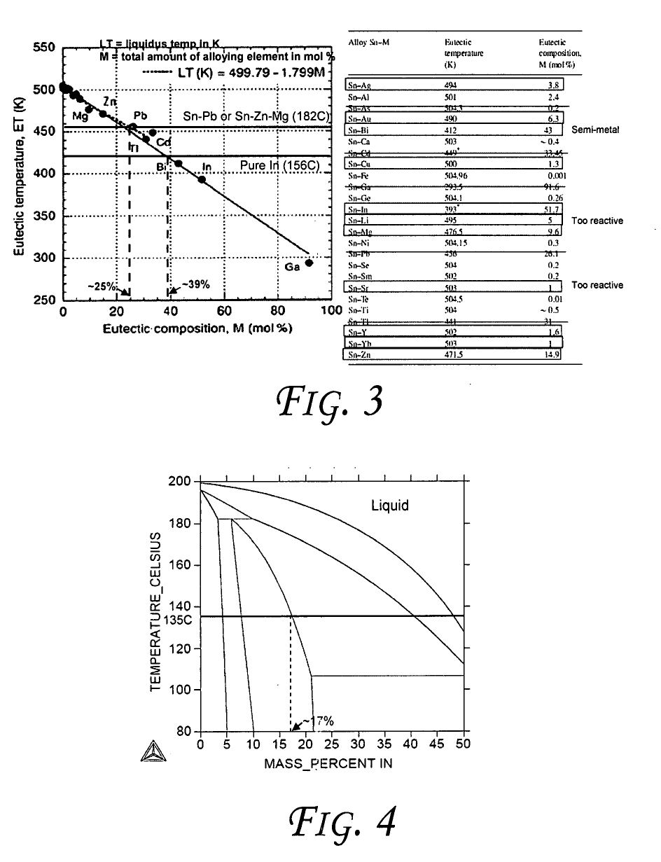

Referring to FIG. 3, the melting point of Sn can be lowered regardless of alloying element as long as the total mol % of alloying element follows the empirical relation shown below. Ternary eutectic Sn—Zn—Mg alloy has about 30 mol % of alloying elemnts (Zn and Mg). Therefore if we add about 9 mol % of alloying element, the melting point would be about 156 C which is the same as pure indium. As illustrated in FIG. 3, alloying elements in Sn which lower the melting point may include Ag, Au, Bi, Cu, In, Y, and Yb.

In another embodiment, the alloy may include a ternary peritectic Sn—In—Zn combination. For example, an alloy comprising Sn (9.9%) In (6.6%) and Zn exhibits Tliquidus=193 C and Tsolidus=179 C.

FIG. 4 is a schematic illustration of a phase diagram for a thermal interface material in accordance with some embodiments. Referring to FIG. 4, an alloy of Sn—In—Zn in a composition of Sn-17% In-5% Zn exhibits a Tliquidus=175 C and Tsolidus=135 C. As illustrated in the vertical section depicted in FIG. 4, this alloy has desirable melting ranges.

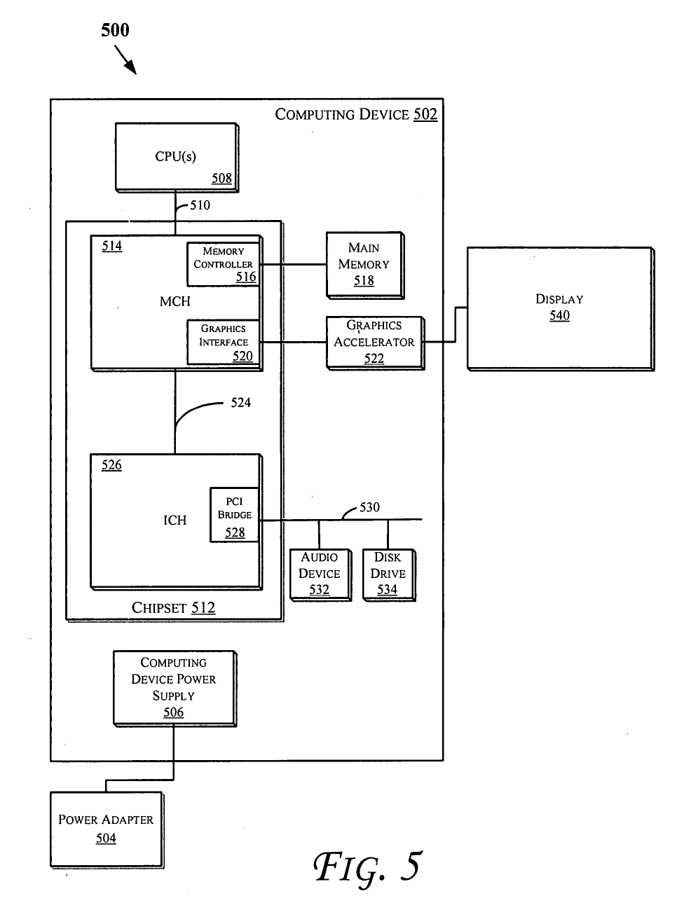

FIG. 5 is a schematic illustration of a computer system 500 in accordance with an embodiment. The computer system 500 includes a computing device 502 and a power adapter 504 (e.g., to supply electrical power to the computing device 502). The computing device 502 may be any suitable computing device such as a laptop (or notebook) computer, a personal digital assistant, a desktop computing device (e.g., a workstation or a desktop computer), a rack-mounted computing device, and the like.

Electrical power may be provided to various components of the computing device 502 (e.g., through a computing device power supply 506) from one or more of the following sources: one or more battery packs, an alternating current (AC) outlet (e.g., through a transformer and/or adaptor such as a power adapter 504), automotive power supplies, airplane power supplies, and the like. In one embodiment, the power adapter 504 may transform the power supply source output (e.g., the AC outlet voltage of about 110 VAC to 240 VAC) to a direct current (DC) voltage ranging between about 7 VDC to 12.6 VDC. Accordingly, the power adapter 504 may be an AC/DC adapter.

The computing device 502 may also include one or more central processing unit(s) (CPUs) 508 coupled to a bus 510. In one embodiment, the CPU 508 may comprise any type of processing device, such as a microprocessor, a network processor, a graphics processor, an application specific integrated circuit (ASIC), a field programmable gate array (FPGA), or other processor, rather than making reference to any specific Intel products.

A chipset 512 may be coupled to the bus 510. The chipset 512 may include a memory control hub (MCH) 514. The MCH 514 may include a memory controller 516 that is coupled to a main system memory 518. The main system memory 518 stores data and sequences of instructions that are executed by the CPU 508, or any other device included in the system 500. In one embodiment, the main system memory 518 includes random access memory (RAM); however, the main system memory 518 may be implemented using other memory types such as dynamic RAM (DRAM), synchronous DRAM (SDRAM), and the like. Additional devices may also be coupled to the bus 510, such as multiple CPUs and/or multiple system memories.

The MCH 514 may also include a graphics interface 520 coupled to a graphics accelerator 522. In one embodiment, the graphics interface 520 is coupled to the graphics accelerator 522 via an accelerated graphics port (AGP). In an embodiment, a display (such as a flat panel display) 540 may be coupled to the graphics interface 520 through, for example, a signal converter that translates a digital representation of an image stored in a storage device such as video memory or system memory into display signals that are interpreted and displayed by the display. The display 540 signals produced by the display device may pass through various control devices before being interpreted by and subsequently displayed on the display.

A hub interface 524 couples the MCH 514 to an input/output control hub (ICH) 526. The ICH 526 provides an interface to input/output (I/O) devices coupled to the computer system 500. The ICH 526 may be coupled to a peripheral component interconnect (PCI) bus. Hence, the ICH 526 includes a PCI bridge 528 that provides an interface to a PCI bus 530. The PCI bridge 528 provides a data path between the CPU 508 and peripheral devices. Additionally, other types of i/O interconnect topologies may be utilized such as the PCI Express™ architecture, available through Intel® Corporation of Santa Clara, Calif.

The PCI bus 530 may be coupled to an audio device 532 and one or more disk drive(s) 534. Other devices may be coupled to the PCI bus 530. In addition, the CPU 508 and the MCH 514 may be combined to form a single chip. Furthermore, the graphics accelerator 522 may be included within the MCH 514 in other embodiments.

Additionally, other peripherals coupled to the ICH 526 may include, in various embodiments, integrated drive electronics (IDE) or small computer system interface (SCSI) hard drive(s), universal serial bus (USB) port(s), a keyboard, a mouse, parallel port(s), serial port(s), floppy disk drive(s), digital output support (e.g., digital video interface (DVI)), and the like. Hence, the computing device 502 may include volatile and/or nonvolatile memory.

In the description and claims, the terms coupled and connected, along with their derivatives, may be used. In particular embodiments, connected may be used to indicate that two or more elements are in direct physical or electrical contact with each other. Coupled may mean that two or more elements are in direct physical or electrical contact. However, coupled may also mean that two or more elements may not be in direct contact with each other, but yet may still cooperate or interact with each other.

Reference in the specification to “one embodiment” “some embodiments” or “an embodiment” means that a particular feature, structure, or characteristic described in connection with the embodiment is included in at least an implementation. The appearances of the phrase “in one embodiment” in various places in the specification may or may not be all referring to the same embodiment.

Although embodiments have been described in language specific to structural features and/or methodological acts, it is to be understood that claimed subject matter may not be limited to the specific features or acts described. Rather, the specific features and acts are disclosed as sample forms of implementing the claimed subject matter.

1. An apparatus, comprising:
a semiconductor device;
a heat dissipation assembly; and
a thermal interface material disposed between the semiconductor device and the heat dissipation assembly, wherein the thermal interface layer comprises an alloy having a low indium content.

2. The apparatus of claim 1, wherein the thermal interface material comprises an alloy of tin and indium.

3. The apparatus of claim 2, wherein the thermal interface alloy comprises tin at a composition between 25 percent and 27 percent weight.

4. The apparatus of claim 2, wherein the thermal interface alloy comprises tin at a composition between 27 percent and 38 percent weight.

5. The apparatus of claim 1, wherein the thermal interface material comprises a ternary peritectic composition of tin, indium, and silver.

6. The apparatus of claim 1, wherein the thermal interface material comprises a ternary eutectic composition of tin, zinc, and magnesium.

7. The apparatus of claim 1, wherein the thermal interface comprises an alloy of tin, zinc, magnesium, and another component selected from the group of components consisting of gold, silver, bismuth, copper, indium, yttrium, and ytterbium.

8. The apparatus of claim 1, wherein the thermal interface comprises a ternary peritectic of tin, indium and zinc.

9. A system, comprising:
a processor coupled to a printed circuit board;
a heat dissipation assembly;
a semiconductor device; and
a thermal interface material disposed between the semiconductor device and the heat dissipation assembly, wherein the thermal interface layer comprises an alloy having a low indium content.

10. The system of claim 9, wherein the thermal interface material comprises an alloy of tin and indium.

11. The system of claim 10, wherein the thermal interface alloy comprises tin at a composition between 25 percent and 27 percent weight.

12. The system of claim 10, wherein the thermal interface alloy comprises tin at a composition between 27 percent and 38 percent weight.

13. The system of claim 9, wherein the thermal interface material comprises a ternary peritectic composition of tin, indium, and silver.

14. The system of claim 9, wherein the thermal interface material comprises a ternary eutectic composition of tin, zinc, and magnesium.

15. The system of claim 9, wherein the thermal interface comprises an alloy of tin, zinc, magnesium, and another component selected from the group of components consisting of gold, silver, bismuth, copper, indium, yttrium, and ytterbium.
